(19) United States
(12) Patent Application Publication
(10) Pub. No.: US 2025/0293138 A1
(43) Pub. Date: Sep. 18, 2025

(54) PACKAGE STRUCTURE AND MANUFACTURING METHOD THEREOF

(71) Applicant: ASPEED Technology Inc., Hsinchu City (TW)

(72) Inventors: Shih-Chao Chiu, Hsinchu City (TW); Cheng-Ju Hsieh, Hsinchu City (TW); Ching-Hua Cheng, Hsinchu City (TW); Teng-Hao Hsu, Hsinchu City (TW)

(73) Assignee: ASPEED Technology Inc., Hsinchu City (TW)

(21) Appl. No.: 18/789,710

(22) Filed: Jul. 31, 2024

(30) Foreign Application Priority Data
Mar. 13, 2024 (TW) 113109157

(51) Int. Cl. H01L 23/498; H01L 23/00; H01L 23/31; H01L 23/367; H01L 25/00; H01L 25/18; H10B 80/00

(52) U.S. Cl. CPC H01L 23/49838; H01L 23/3128; H01L 23/3672; H01L 23/49833; H01L 24/16; H01L 24/32; H01L 24/48; H01L 24/73; H01L 25/18; H01L 25/50; H01L 2224/16225; H01L 2224/32225; H01L 2224/48225; H01L 2224/73204; H01L 2924/1433; H01L 2924/14361; H10B 80/00

(57) ABSTRACT

A package structure includes a first circuit substrate, a control circuit chip, a memory chip, a second circuit substrate, a plurality of conductive elements, a molding compound, and a plurality of solder balls. The control circuit chip and the memory chip are respective disposed on a first side and a second side of the first circuit substrate and electrically connected to the first circuit substrate. The memory chip, the conductive elements, and the molding compound are located between the second side of the first circuit substrate and a third side of the second circuit substrate. The conductive elements are electrically connected to the first circuit substrate and the second circuit substrate, and the molding compound covers the memory chip and the conductive elements. The solder balls are disposed on a fourth side of the second circuit substrate and electrically connected to the second circuit substrate.

### CROSS-REFERENCE TO RELATED APPLICATION

This application claims the priority benefit of Taiwan application serial no. 113109157, filed on Mar. 13, 2024. The entirety of the above-mentioned patent application is hereby incorporated by reference herein and made a part of specification.

### BACKGROUND OF THE INVENTION

### Field of the Invention

The invention relates to a semiconductor structure and a manufacturing method thereof, and particularly relates to a package structure and a manufacturing method thereof.

### Description of Related Art

In existing package on package (POP), the processor (such as application-specific integrated circuit (ASIC)) is located in the exact middle of the entire package, that is, located between two circuit substrates and covered by a molding compound. Therefore, the heat dissipation effect of the overall package structure is poor and the chip performance of the processor may not be effectively improved.

### SUMMARY OF THE INVENTION

The invention provides a package structure having better heat dissipation effect and may effectively improve the performance of a control circuit chip.

The invention further provides a manufacturing method of a package structure for manufacturing the package structure.

A package structure of the invention includes a first circuit substrate, a control circuit chip, a memory chip, a second circuit substrate, a plurality of conductive elements, a molding compound, and a plurality of solder balls. The first circuit substrate has a first side and a second side opposite to each other. The control circuit chip is disposed on the first side of the first circuit substrate and electrically connected to the first circuit substrate. The memory chip is disposed on the second side of the first circuit substrate and electrically connected to the first circuit substrate. The second circuit substrate has a third side and a fourth side opposite to each other, wherein the memory chip is located between the second side of the first circuit substrate and the third side of the second circuit substrate. The conductive elements are disposed between the second side of the first circuit substrate and the third side of the second circuit substrate and electrically connected to the first circuit substrate and the second circuit substrate. The molding compound is disposed between the second side of the first circuit substrate and the third side of the second circuit substrate and covers the memory chip and the conductive elements. The solder balls are disposed on the fourth side of the second circuit substrate and electrically connected to the second circuit substrate.

In an embodiment of the invention, the control circuit chip includes an application-specific integrated circuit (ASIC) chip, and the memory chip includes a double data rate synchronous dynamic random-access memory (DDR SDRAM).

In an embodiment of the invention, the package structure further includes a plurality of solder bumps disposed between the control circuit chip and the first circuit substrate. The control circuit chip includes a plurality of pads, and the pads are electrically connected to the first circuit substrate via the solder bumps.

In an embodiment of the invention, the package structure also includes an underfill disposed between the control circuit chip and the first circuit substrate and covering the pads and the solder bumps.

In an embodiment of the invention, the package structure further includes a plurality of solder bumps disposed between the memory chip and the first circuit substrate. The memory chip includes a plurality of pads, and the pads are electrically connected to the first circuit substrate via the solder bumps.

In an embodiment of the invention, the package structure also includes an underfill disposed between the memory chip and the first circuit substrate and covering the pads and the solder bumps.

In an embodiment of the invention, the package structure further includes a plurality of wires disposed between the memory chip and the first circuit substrate. The memory chip is electrically connected to the first circuit substrate via the wires.

In an embodiment of the invention, each of the conductive elements includes a solder ball, a metal pillar, or a solder covering a metal ball.

In an embodiment of the invention, the package structure further includes a heat dissipation block disposed on a back surface of the control circuit chip relatively far away from the first circuit substrate.

In an embodiment of the invention, an orthographic projection of the control circuit chip on the first circuit substrate is completely overlapped with an orthographic projection of the memory chip on the first circuit substrate.

A manufacturing method of a package structure of the invention includes the following steps. A first circuit substrate is provided. The first circuit substrate has a first side and a second side opposite to each other. A control circuit chip and a memory chip are provided. The control circuit chip is disposed on the first side of the first circuit substrate and electrically connected to the first circuit substrate. The memory chip is disposed on the second side of the first circuit substrate and electrically connected to the first circuit substrate. A second circuit substrate is provided. The second circuit substrate has a third side and a fourth side opposite to each other, wherein the memory chip is located between the second side of the first circuit substrate and the third side of the second circuit substrate. A plurality of conductive elements are formed between the second side of the first circuit substrate and the third side of the second circuit substrate. The conductive elements are electrically connected to the first circuit substrate and the second circuit substrate. A molding compound is formed between the second side of the first circuit substrate and the third side of the second circuit substrate to cover the memory chip and the conductive elements. A plurality of solder balls are formed on the fourth side of the second circuit substrate, wherein the plurality of solder balls are electrically connected to the second circuit substrate.

In an embodiment of the invention, the control circuit chip includes an application-specific integrated circuit (ASIC) chip, and the memory chip includes a double data rate synchronous dynamic random-access memory (DDR SDRAM).

In an embodiment of the invention, the manufacturing method of the package structure further includes forming a plurality of solder bumps between the control circuit chip and the first circuit substrate. The control circuit chip includes a plurality of pads, and the pads are electrically connected to the first circuit substrate via the solder bumps.

In an embodiment of the invention, the manufacturing method of the package structure also includes filling an underfill between the control circuit chip and the first circuit substrate and covering the pads and the solder bumps.

In an embodiment of the invention, the manufacturing method of the package structure further includes forming a plurality of solder bumps between the memory chip and the first circuit substrate. The memory chip includes a plurality of pads, and the pads are electrically connected to the first circuit substrate via the solder bumps.

In an embodiment of the invention, the manufacturing method of the package structure also includes filling an underfill between the memory chip and the first circuit substrate and covering the pads and the solder bumps.

In an embodiment of the invention, the manufacturing method of the package structure further includes forming a plurality of wires between the memory chip and the first circuit substrate. The memory chip is electrically connected to the first circuit substrate via the wires.

In an embodiment of the invention, each of the conductive elements includes a solder ball, a metal pillar, or a solder covering a metal ball.

In an embodiment of the invention, the manufacturing method of the package structure further includes disposing a heat dissipation block on a back surface of the control circuit chip relatively far away from the first circuit substrate.

In an embodiment of the invention, an orthographic projection of the control circuit chip on the first circuit substrate is completely overlapped with an orthographic projection of the memory chip on the first circuit substrate.

Based on the above, in the design of the package structure of the invention, the control circuit chip and the memory chip are respectively disposed on the first side and the second side of the first circuit substrate, and the molding compound covers the memory chip and the conductive elements. In other words, the control circuit chip of the invention is not covered by the molding compound but is exposed to the outside. Therefore, the heat dissipation effect of the package structure of the invention may be significantly increased, thereby effectively improving the performance of the control circuit chip.

In order to make the aforementioned features and advantages of the disclosure more comprehensible, embodiments accompanied with figures are described in detail below.

### BRIEF DESCRIPTION OF THE DRAWINGS

FIG. 1A to FIG. 1D are schematic cross-sectional views of a manufacturing method of a package structure according to an embodiment of the invention.

FIG. 2 is a schematic cross-sectional view of a package structure according to an embodiment of the invention.

FIG. 3 is a schematic cross-sectional view of a package structure according to another embodiment of the invention.

FIG. 4 is a schematic cross-sectional view of a package structure according to another embodiment of the invention.

FIG. 5 is a schematic cross-sectional view of a package structure according to another embodiment of the invention.

### DESCRIPTION OF THE EMBODIMENTS

The embodiments of the invention may be understood together with the drawings, and the drawings of the invention are also regarded as a part of the disclosure. It should be understood that the drawings of the invention are not drawn to scale and, in fact, the dimensions of elements may be arbitrarily expanded or reduced in order to clearly represent the features of the invention.

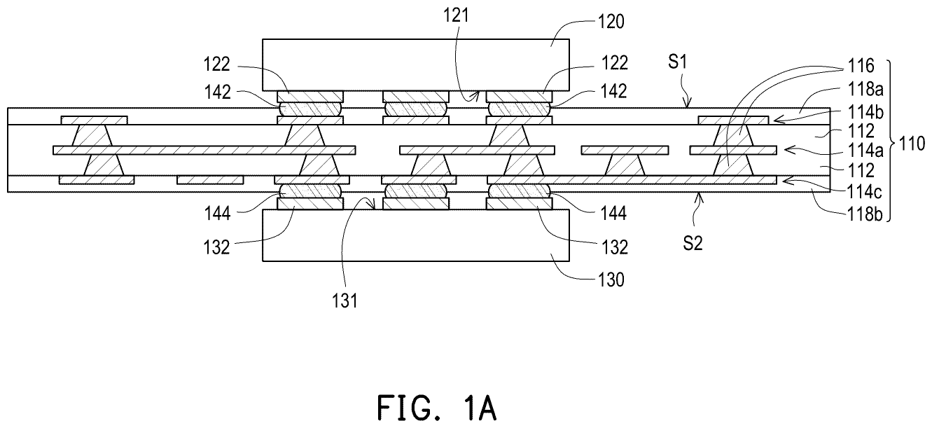

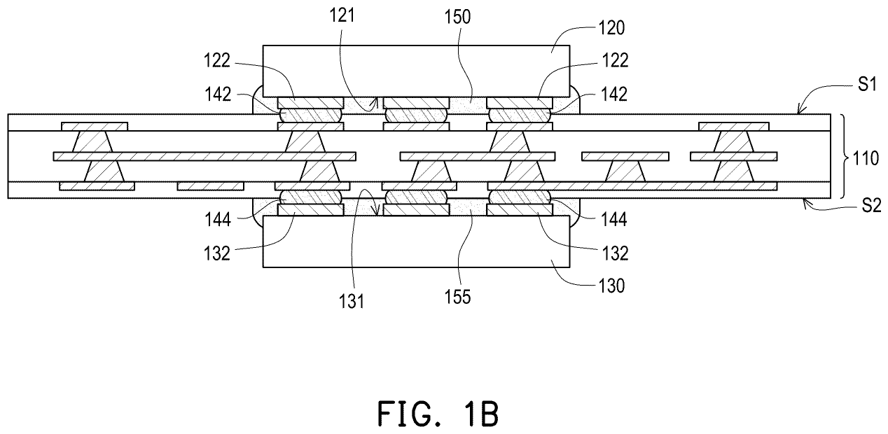

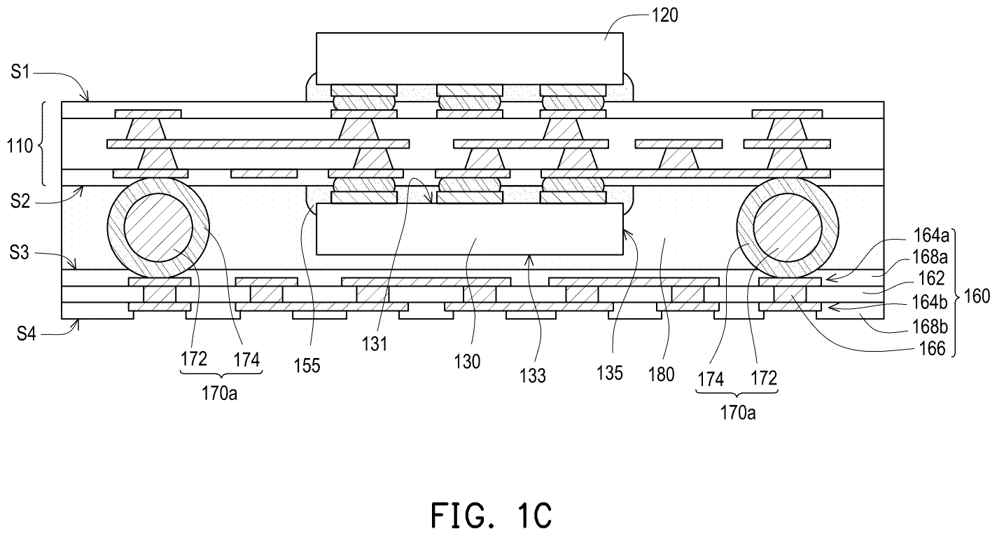

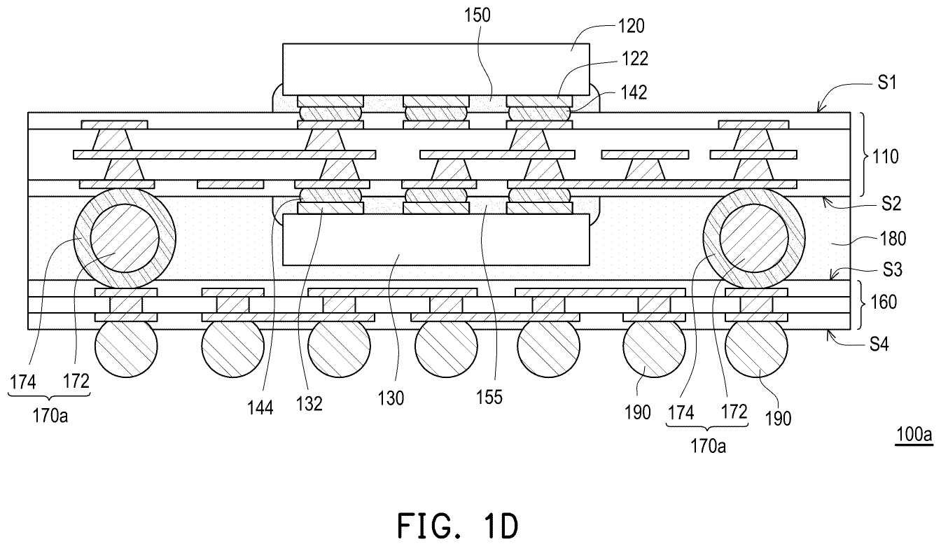

FIG. 1A to FIG. 1D are schematic cross-sectional views of a manufacturing method of a package structure according to an embodiment of the invention. According to the manufacturing method of the package structure of the present embodiment, first, referring to FIG. 1A, a first circuit substrate 110 is provided. The first circuit substrate 110 has a first side S1 and a second side S2 opposite to each other and includes a plurality of dielectric layers 112, a plurality of patterned circuit layers 114a, 114b, 114c, a plurality of conductive blind holes 116, and a plurality of solder resist layers 118a and 118b. The dielectric layer 112 and the patterned circuit layers 114a, 114b, and 114c are alternately stacked, and the conductive blind holes 116 are electrically connected to the patterned circuit layers 114a, 114b, and 114c. The patterned circuit layer 114a is located between the patterned circuit layer 114b and the patterned circuit layer 114c, and the solder resist layers 118a and 118b cover the patterned circuit layers 114b and 114c respectively and partially expose the patterned circuit layers 114b and 114c respectively, wherein the solder resist layers 118a and 118b respectively have the first side S1 and the second side S2.

It should be mentioned that, the present embodiment does not limit the quantity of the dielectric layer 112 and the patterned circuit layers 114a, 114b, 114c of the first circuit substrate 110, and the quantity may be arbitrarily increased or decreased according to use requirements.

Next, please refer to FIG. 1A again, a control circuit chip 120 and a memory chip 130 are provided. The control circuit chip 120 is disposed on the first side S1 of the first circuit substrate 110 and electrically connected to the first circuit substrate 110. The memory chip 130 is disposed on the second side S2 of the first circuit substrate 110 and electrically connected to the first circuit substrate 110. In an embodiment, the circuit chip 120 may be, for example, an application-specific integrated circuit (ASIC) chip, and the memory chip 130 may be, for example, a double data rate synchronous dynamic random-access memory (DDR SDRAM).

More specifically, an active surface 121 of the control circuit chip 120 includes a plurality of pads 122, and a plurality of solder bumps 142 may be formed on the pads 122 of the control circuit chip 120 first. Then, via flip-chip bonding, the solder bumps 142 may be electrically connected to the patterned circuit layer 114b exposed by the solder resist layer 118a on the first circuit substrate 110. At this point, the solder bumps 142 are formed between the control circuit chip 120 and the first circuit substrate 110, and the pads 122 of the control circuit chip 120 are electrically connected to the first circuit substrate 110 via the solder bumps 142 respectively.

Similarly, an active surface 131 of the memory chip 130 includes a plurality of pads 132, and a plurality of solder bumps 144 may be formed on the pads 132 of the memory chip 130 first. Then, via flip-chip bonding, the solder bumps 144 may be electrically connected to the patterned circuit layer 114c exposed by the solder resist layer 118b on the first circuit substrate 110. At this point, the solder bumps 144 are formed between the memory chip 130 and the first circuit substrate 110, and the pads 132 of the memory chip 130 are electrically connected to the first circuit substrate 110 via the solder bumps 144 respectively. At this point, the bonding of the control circuit chip 120 and the memory chip 130 to the first side S1 and the second side S2 of the first circuit substrate 110 is complete.

It should be noted that in other embodiments, the solder bumps 142 and 144 may also be formed first on the patterned circuit layers 114b and 114c exposed by the solder resist layers 118a and 118b on the first circuit substrate 110. Next, the pads 122 of the control circuit chip 120 and the pads 132 of the memory chip 130 are electrically connected to the solder bumps 142 and 144 on the first circuit substrate 110 respectively, and this is still within the scope of the invention.

Next, please refer to FIG. 1B, in order to protect the pads 122 and the solder bumps 142 and ensure the bonding between the control circuit chip 120 and the first circuit substrate 110, the present embodiment also includes filling an underfill 150 between the control circuit chip 120 and the first circuit substrate 110, wherein the underfill 150 covers the pads 122 and the solder bumps 142 and may directly be in contact with the active surface 121 of the control circuit chip 120. Similarly, in order to protect the pads 132 and the solder bumps 144 and ensure the bonding between the memory chip 130 and the first circuit substrate 110, the present embodiment also includes filling an underfill 155 between the memory chip 130 and the first circuit substrate 110, wherein the underfill 155 covers the pads 132 and the solder bumps 144 and may directly be in contact with the active surface 131 of the memory chip 130. In an embodiment, the material of the underfill 150 and 155 may be, for example, resin, epoxy resin, or molding compound, but not limited thereto.

Next, referring to FIG. 1C, a second circuit substrate 160 is provided. The second circuit substrate 160 has a third side S3 and a fourth side S4 opposite to each other and includes a dielectric layer 162, a plurality of patterned circuit layers 164a and 164b, a plurality of conductive blind holes 166, and a plurality of solder resist layers 168a and 168b. The dielectric layer 162 and the patterned circuit layers 164a and 164b are alternately stacked, and the conductive blind holes 166 are electrically connected to the patterned circuit layers 164a and 164b. The solder resist layers 168a and 168b cover the patterned circuit layers 164a and 164b respectively and partially expose the patterned circuit layers 164a and 164b respectively, wherein the solder resist layers 168a and 168b respectively have the third side S3 and the fourth side S4. At this time, the memory chip 130 is located between the second side S2 of the first circuit substrate 110 and the third side S3 of the second circuit substrate 160.

Next, referring further to FIG. 1C, a plurality of conductive elements 170a are formed between the second side S2 of the first circuit substrate 110 and the third side S3 of the second circuit substrate 160, wherein the conductive elements 170a are electrically connected to the first circuit substrate 110 and the second circuit substrate 160. In the present embodiment, each of the conductive elements 170a is, for example, a solder 174 covering a metal ball 172, wherein the material of the metal ball 172 may include copper, silver, tin, or other highly conductive materials, and the material of the solder 174 may include tin (Sn), lead-free solder, tin-indium (Sn—In), tin-lead (Sn—Pb), tin-bismuth (Sn—Bi), or tin-silver-copper (Sn—Ag—Cu), and is not limited thereto.

It should be noted that the invention does not limit the order of providing the second circuit substrate 160 and forming the conductive elements 170a. In an embodiment, the conductive elements 170a may be formed on the second side S2 of the first circuit substrate 110 first, and then the second circuit substrate 160 is provided to be electrically connected to the conductive elements 170a. In another embodiment, the second circuit substrate 160 may be provided first, and then the conductive elements 170a are formed on the third side S3 of the second circuit substrate 160. Next, the conductive elements 170a are electrically connected to the second side S2 of the first circuit substrate 110. Moreover, the present embodiment does not limit the quantity of the dielectric layer 162 and the patterned circuit layers 164a and 164b of the second circuit substrate 160, and the quantity may be arbitrarily increased according to use requirements.

Next, referring further to FIG. 1C, a molding compound 180 is formed between the second side S2 of the first circuit substrate 110 and the third side S3 of the second circuit substrate 160 to cover the memory chip 130 and the conductive elements 170a. Here, the molding compound 180 completely covers a back surface 133 of the memory chip 130 relative to the active surface 131 and a surrounding surface 135 connected to the active surface 131 and the back surface 133, the underfill 155, and the conductive elements 170a. In other words, the control circuit chip 120 of the present embodiment is exposed to the outside and is not covered by the molding compound 180, thus facilitating heat dissipation.

Lastly, referring to FIG. 1D, a plurality of solder balls 190 are formed on the fourth side S4 of the second circuit substrate 160 and electrically connected to the second circuit substrate 160, wherein the second circuit substrate 160 may be electrically connected to an external circuit (such as a printed circuit board, not shown) via the solder balls 190. At this point, the manufacture of a package structure 100a is completed.

Please refer further to FIG. 1D. Structurally, the package structure 100a includes the first circuit substrate 110, the control circuit chip 120, the memory chip 130, the second circuit substrate 160, the conductive elements 170a, the molding compound 180, and the solder balls 190. The first circuit substrate 110 has the first side S1 and the second side S2 opposite to each other. The control circuit chip 120 is disposed on the first side S1 of the first circuit substrate 110 and electrically connected to the first circuit substrate 110, wherein the control circuit chip 120 may be, for example, an application-specific integrated circuit chip. The control circuit chip 130 is disposed on the second side S2 of the first circuit substrate 110 and electrically connected to the first circuit substrate 110, wherein the memory chip 130 may be, for example, a double data rate synchronous dynamic random-access memory. The second circuit substrate 160 has the third side S3 and the fourth side S4 opposite to each other, wherein the memory chip 130 is located between the second side S2 of the first circuit substrate 110 and the third side S3 of the second circuit substrate 160. The conductive elements 170a are disposed between the second side S2 of the first circuit substrate 110 and the third side S3 of the second circuit substrate 160 and electrically connected to the first circuit substrate 110 and the second circuit substrate 160. The molding compound 180 is disposed between the second side S2 of the first circuit substrate 110 and the third side S3 of the second circuit substrate 160 and covers the memory chip 130 and the conductive elements 170a. The solder balls 190 are disposed on the fourth side S4 of the second circuit substrate 160 and electrically connected to the second circuit substrate 160.

Furthermore, the package structure 100a of the present embodiment also includes the solder bumps 142 disposed between the control circuit chip 120 and the first circuit substrate 110. The control circuit chip 120 includes the pads 122, and the pads 122 are electrically connected to the first circuit substrate 110 via the solder bumps 142. That is, the control circuit chip 120 is disposed on the first side S1 of the first circuit substrate 110 in a flip-chip bonding manner. Similarly, the package structure 100a of the present embodiment also includes the solder bumps 144 disposed between the memory chip 130 and the first circuit substrate 110. The memory chip 130 includes the pads 132, and the pads 132 are electrically connected to the first circuit substrate 110 via the solder bumps 144. That is, the memory chip 130 is disposed on the second side S2 of the first circuit substrate 110 in a flip-chip bonding manner.

Moreover, the package structure 100a of the present embodiment also includes the underfill 150 disposed between the control circuit chip 120 and the first circuit substrate 110 and covering the pads 122 and the solder bumps 142. The arrangement of the underfill 150 may effectively protect the pads 122 and the solder bumps 142 of the control circuit chip 120 and ensure the bonding between the control circuit chip 120 and the first circuit substrate 110. Similarly, the package structure 100a of the present embodiment also includes the underfill 155 disposed between the memory chip 130 and the first circuit substrate 110 and covering the pads 132 and the solder bumps 144. The arrangement of the underfill 155 may effectively protect the pads 132 and the solder bumps 144 of the memory chip 130 and ensure the bonding between the memory chip 130 and the first circuit substrate 110.

In the present embodiment, an orthographic projection of the control circuit chip 120 on the first circuit substrate 110 may be completely overlapped with an orthographic projection of the memory chip 130 on the first circuit substrate 110. That is, the package structure 100a of the present embodiment belongs to the package-on-package (POP). The control circuit chip 120 is electrically connected to the memory chip 130 via the solder bumps 142, the first circuit substrate 110, and the solder bumps 144 to achieve the electrical connection between chips so that the signal transmission path is shorter. Moreover, the first circuit substrate 110 is electrically connected to an external circuit (such as a printed circuit board, not shown) via the conductive elements 170a, the second circuit substrate 160, and the solder balls 190 to achieve the electrical connection between the package structure 100a and the external circuit.

In short, in an embodiment, the control circuit chip 120 and the memory chip 130 are respectively disposed on the first side S1 and the second side S2 of the first circuit substrate 110, and the molding compound 180 covers the memory chip 130 and the conductive elements 170a. In other words, the control circuit chip 120 of the present embodiment is not covered by the molding compound 180 but is exposed to the outside. Therefore, the heat dissipation effect of the package structure 100a may be significantly increased, thereby effectively improving the performance of the control circuit chip 180.

Moreover, the control circuit chip 120 and the memory chip 130 are respectively electrically connected to the first circuit substrate 110 in a flip-chip bonding manner. Therefore, the signal transmission path between the control circuit chip 120 and the memory chip 130 is shorter to significantly improve the transmission efficiency of the control circuit chip 120.

Other embodiments are listed below for illustration. It should be mentioned that, the embodiments below adopt the same reference numerals and portions of the content from previous embodiments. Specifically, the same reference numerals are used to represent the same or similar elements, and the descriptions for the same techniques are omitted. The omitted portions are as described in the embodiments above and are not repeated in the embodiments below.

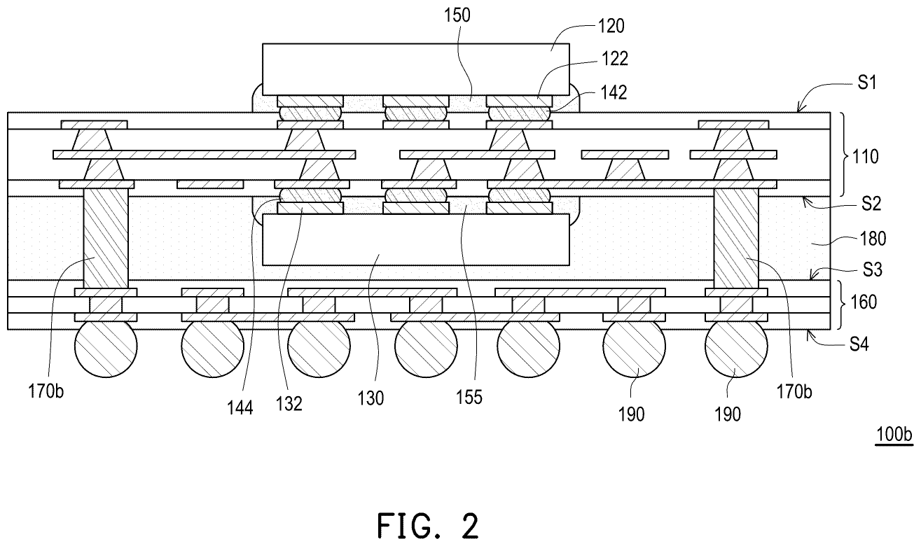

FIG. 2 is a schematic cross-sectional view of a package structure according to an embodiment of the invention. Please refer to FIG. 1D and FIG. 2 at the same time. A package structure 100b of the present embodiment is similar to the package structure 100a, but the main differences between the two are: in the present embodiment, each of the conductive elements 170 is, for example, a metal pillar, wherein the material of the metal pillar may include copper, silver, tin, or other highly conductive materials, and is not limited thereto.

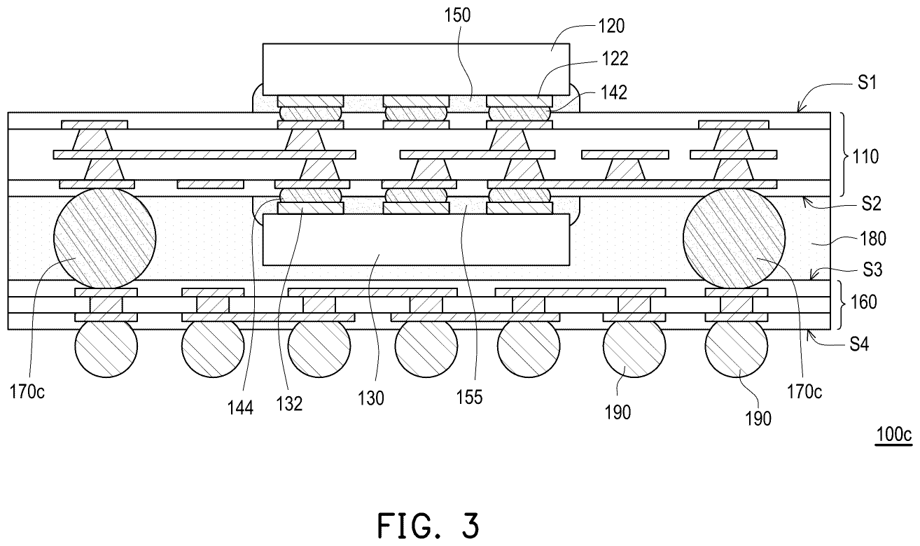

FIG. 3 is a schematic cross-sectional view of a package structure according to another embodiment of the invention. Please refer to FIG. 1D and FIG. 3 at the same time. A package structure 100c of the present embodiment is similar to the package structure 100a, but the main differences between the two are: in the present embodiment, each of the conductive elements 170 is, for example, a solder ball, wherein the material of the solder ball includes tin (Sn), lead-free solder, tin-indium (Sn—In), tin-lead (Sn—Pb), tin-bismuth (Sn—Bi), or tin-silver-copper (Sn—Ag—Cu), and is not limited thereto.

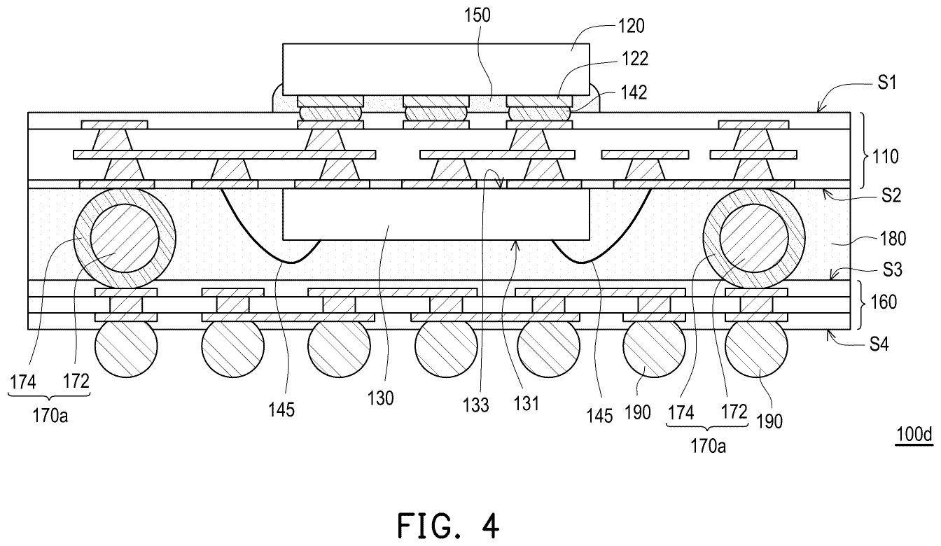

FIG. 4 is a schematic cross-sectional view of a package structure according to another embodiment of the invention. Please refer to FIG. 1D and FIG. 4 at the same time. A package structure 100d of the present embodiment is similar to the package structure 100a, but the main differences between the two are: in the present embodiment, the package structure 100d also includes a plurality of wires 145 disposed between the memory chip 130 and the first circuit substrate 110, wherein the memory chip 130 is electrically connected to the first circuit substrate 110 via the wires 145. In an embodiment, the material of the wires 145 is, for example, gold or other suitable metal materials, but is not limited thereto. In short, the memory chip 130 of the present embodiment is electrically connected to the first circuit substrate 110 in a wire bonding manner.

In terms of production, when the memory chip 130 is provided in FIG. 1A, the memory chip 130 is disposed on the second side S2 of the first circuit substrate 110 via the back surface 133. That is, the active surface 131 of the memory chip 130 is relatively far away from the second side S2 of the first circuit substrate 110. Then, the plurality of wires 145 are formed between the active surface 131 of the memory chip 130 and the first circuit substrate 110 so that the memory chip 130 is electrically connected to the first circuit substrate 110 via the wires 145. In other words, in the package structure 100d of the present embodiment, the control circuit chip 120 is bonded to the first side S1 of the first circuit substrate 110 in a flip-chip bonding manner, and the memory chip 130 is bonded to the second side S2 of the first circuit substrate 110 in a wire bonding manner. Compared with the existing technique that uses wire bonding to form a stacked package structure of the control circuit chip and the memory chip, the present embodiment only uses wire bonding for the combination of the memory chip 130 and the first circuit substrate 110, thus effectively reducing the package thickness and volume of the package structure 100d.

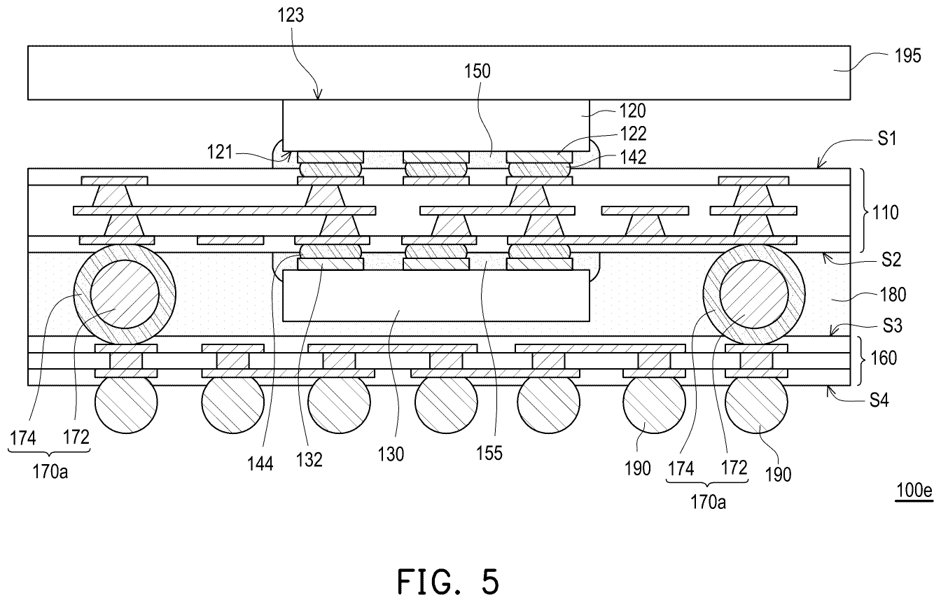

FIG. 5 is a schematic cross-sectional view of a package structure according to another embodiment of the invention. Please refer to FIG. 1D and FIG. 5 at the same time. A package structure 100e of the present embodiment is similar to the package structure 100a, but the main differences between the two are: in the present embodiment, the package structure 100e also includes a heat dissipation block 195 disposed on a back surface 123 of the control circuit chip 120 relatively far away from the first circuit substrate 110 to further increase the heat dissipation effect of the package structure 100e, thereby improving the performance of the control circuit chip 120 more effectively.

In terms of production, after the step of FIG. 1C, that is, after the molding compound 180 is formed between the second side S2 of the first circuit substrate 110 and the third side S3 of the second circuit substrate 160, the heat dissipation block 195 may be disposed on the back surface 123 of the control circuit chip 120 relatively far away from the first circuit substrate 110. In other words, the present embodiment does not limit the order of forming the solder balls 190 and arranging the heat dissipation block 195, which may be arbitrarily determined according to process requirements.

Based on the above, in the design of the package structure of the invention, the control circuit chip and the memory chip are respectively disposed on the first side and the second side of the first circuit substrate, and the molding compound covers the memory chip and the conductive elements. In other words, the control circuit chip of the invention is not covered by the molding compound but is exposed to the outside. Therefore, the heat dissipation effect of the package structure of the invention may be significantly increased, thereby effectively improving the performance of the control circuit chip.

Although the invention has been described with reference to the above embodiments, it will be apparent to one of ordinary skill in the art that modifications to the described embodiments may be made without departing from the spirit of the disclosure. Accordingly, the scope of the disclosure is defined by the attached claims not by the above detailed descriptions.

What is claimed is:

1. A package structure, comprising:
a first circuit substrate having a first side and a second side opposite to each other;
a control circuit chip disposed on the first side of the first circuit substrate and electrically connected to the first circuit substrate;
a memory chip disposed on the second side of the first circuit substrate and electrically connected to the first circuit substrate;
a second circuit substrate having a third side and a fourth side opposite to each other, wherein the memory chip is located between the second side of the first circuit substrate and the third side of the second circuit substrate;
a plurality of conductive elements disposed between the second side of the first circuit substrate and the third side of the second circuit substrate and electrically connected to the first circuit substrate and the second circuit substrate;
a molding compound disposed between the second side of the first circuit substrate and the third side of the second circuit substrate and covering the memory chip and the conductive elements; and
a plurality of solder balls disposed on the fourth side of the second circuit substrate and electrically connected to the second circuit substrate.

2. The package structure of claim 1, wherein the control circuit chip comprises an application-specific integrated circuit chip, and the memory chip comprises a double data rate synchronous dynamic random-access memory.

3. The package structure of claim 1, further comprising:
a plurality of solder bumps disposed between the control circuit chip and the first circuit substrate, wherein the control circuit chip comprises a plurality of pads, and the pads are electrically connected to the first circuit substrate via the solder bumps.

4. The package structure of claim 3, further comprising:
an underfill disposed between the control circuit chip and the first circuit substrate and covering the pads and the solder bumps.

5. The package structure of claim 1, further comprising:
a plurality of solder bumps disposed between the memory chip and the first circuit substrate, wherein the memory chip comprises a plurality of pads, and the pads are electrically connected to the first circuit substrate via the solder bumps.

6. The package structure of claim 5, further comprising:
an underfill disposed between the memory chip and the first circuit substrate and covering the pads and the solder bumps.

7. The package structure of claim 1, further comprising:
a plurality of wires disposed between the memory chip and the first circuit substrate, wherein the memory chip is electrically connected to the first circuit substrate via the wires.

8. The package structure of claim 1, wherein each of the conductive elements comprises a solder ball, a metal pillar, or a solder covering a metal ball.

9. The package structure of claim 1, further comprising:
a heat dissipation block disposed on a back surface of the control circuit chip relatively far away from the first circuit substrate.

10. The package structure of claim 1, wherein an orthographic projection of the control circuit chip on the first circuit substrate is completely overlapped with an orthographic projection of the memory chip on the first circuit substrate.

11. A manufacturing method of a package structure, comprising:
providing a first circuit substrate, wherein the first circuit substrate has a first side and a second side opposite to each other;
providing a control circuit chip and a memory chip, wherein the control circuit chip is disposed on the first side of the first circuit substrate and electrically connected to the first circuit substrate, and the memory chip is disposed on the second side of the first circuit substrate and electrically connected to the first circuit substrate;
providing a second circuit substrate, wherein the second circuit substrate has a third side and a fourth side opposite to each other, and the memory chip is located between the second side of the first circuit substrate and the third side of the second circuit substrate;
forming a plurality of conductive elements between the second side of the first circuit substrate and the third side of the second circuit substrate, wherein the conductive elements are electrically connected to the first circuit substrate and the second circuit substrate;
forming a molding compound between the second side of the first circuit substrate and the third side of the second circuit substrate to cover the memory chip and the conductive elements; and
forming a plurality of solder balls on the fourth side of the second circuit substrate, wherein the plurality of solder balls are electrically connected to the second circuit substrate.

12. The manufacturing method of the package structure of claim 11, wherein the control circuit chip comprises an application-specific integrated circuit chip, and the memory chip comprises a double data rate synchronous dynamic random-access memory.

13. The manufacturing method of the package structure of claim 11, further comprising:
forming a plurality of solder bumps between the control circuit chip and the first circuit substrate, wherein the control circuit chip comprises a plurality of pads, and the pads are electrically connected to the first circuit substrate via the solder bumps.

14. The manufacturing method of the package structure of claim 13, further comprising:
filling an underfill between the control circuit chip and the first circuit substrate and covering the pads and the solder bumps.

15. The manufacturing method of the package structure of claim 11, further comprising:
forming a plurality of solder bumps between the memory chip and the first circuit substrate, wherein the memory chip comprises a plurality of pads, and the pads are electrically connected to the first circuit substrate via the solder bumps.

16. The manufacturing method of the package structure of claim 15, further comprising:
filling an underfill between the memory chip and the first circuit substrate and covering the pads and the solder bumps.

17. The manufacturing method of the package structure of claim 11, further comprising:
forming a plurality of wires between the memory chip and the first circuit substrate, wherein the memory chip is electrically connected to the first circuit substrate via the wires.

18. The manufacturing method of the package structure of claim 11, wherein each of the conductive elements comprises a solder ball, a metal pillar, or a solder covering a metal ball.

19. The manufacturing method of the package structure of claim 11, further comprising:
disposing a heat dissipation block on a back surface of the control circuit chip relatively far away from the first circuit substrate.

20. The manufacturing method of the package structure of claim 11, wherein an orthographic projection of the control circuit chip on the first circuit substrate is completely overlapped with an orthographic projection of the memory chip on the first circuit substrate.
